(19) United States
(12) Patent Application Publication
(10) Pub. No.: US 2017/0287881 A1
(43) Pub. Date: Oct. 5, 2017

(54) SEMICONDUCTOR ELEMENT AND MANUFACTURING METHOD THEREOF

(71) Applicant: KAISTAR Lighting (Xiamen) Co., Ltd, Xiamen (CN)

(72) Inventors: Weihong Yang, Xiamen (CN); Shenbo Lin, Xiamen (CN); Zhiwei Huang, Xiamen (CN)

(21) Appl. No.: 15/390,555

(22) Filed: Dec. 26, 2016

(30) Foreign Application Priority Data
Mar. 31, 2016 (CN) 201610194356.2

(51) Int. Cl. H01L 25/075; H01L 33/62; H01L 33/48; H01L 33/64

(52) U.S. Cl. CPC H01L 25/0753; H01L 33/644; H01L 33/62; H01L 33/483; H01L 2933/0066; H01L 2933/0075; H01L 2225/06555; H01L 2225/06589

(57) ABSTRACT

A semiconductor element and a manufacturing method thereof are provided. The semiconductor element includes a substrate and multiple semiconductor chips disposed thereon. The semiconductor chips are arranged to form multiple sequentially nested circle(s), and a circumference of each of which is arranged with multiple the semiconductor chips. The numbers of the semiconductor chips arranged on the respective circumferences of the sequentially nested circle(s) from inside to outside are gradually increased, and distances among the circumferences are gradually decreased from inside to outside. The disclosure optimizes the arrangement of the semiconductor chips to make the arrangement of the semiconductor chips be loose in the central region while more dense towards outside, which is in favor of uniform heat distribution and therefore can slow down aging and failure of the semiconductor chips and improve heat dissipation performance and light emitting effect of product.

### CROSS-REFERENCE TO RELATED APPLICATIONS

This application is based on and claims priority to Chinese Patent Application No. 201610194356.2, filed on Mar. 31, 2016, the full disclosure of which is hereby incorporated by reference in its entirety.

### TECHNICAL FIELD

The disclosure relates to a semiconductor element technical field, and more particularly to a structure of a semiconductor element and a manufacturing method thereof.

### BACKGROUND

In a field of semiconductor element such as light-emitting diode (LED) packaging technology, arrangement of LED chips diversifies with introduction of a mirror aluminum substrate and a ceramic substrate. A conventional arrangement in the mainstream is an equidistant arrangement, as shown in FIG. 1, distances between LED chips disposed in a circular die bonding region are equidistant in a direction of horizontal axis (row direction) as well as in a direction of vertical axis (column direction). Another conventional arrangement in the mainstream is circular arrangement (or non-equidistant arrangement), distances between LED chips are non-equidistant in directions of horizontal axis and vertical axis, and the number of LED chips on each circumference is generally identical. Moreover, it can be understood that after the LED chips are arranged on a substrate, a packaging lens (e.g., silicone lens) is used to cover and seal arranged LED chips so that the LED chips are encapsulated between the substrate and the packaging lens, in order to form a LED packaging structure.

The circular arrangement is preferred due to better performances of heat dissipation and light-emitting effects, however the conventional circular arrangement is difficult to maximize the advantages of heat dissipation and light emission, hence it needs to be further improved.

### SUMMARY

Therefore, an objective of the disclosure is to provide a semiconductor element and a manufacturing method thereof for improving heat dissipation performance and light-emitting effect of product.

Specifically, a semiconductor element provided by an embodiment of the disclosure includes a substrate and a plurality of semiconductor chips disposed on the substrate. The plurality of semiconductor chips are arranged to form a plurality of sequentially nested circle(s), and the plurality of semiconductor chips are arranged on circumferences of each of the circle(s) or approximate circle(s). The amount of the semiconductor chips arranged on each of the circumferences of the plurality of sequentially nested circle(s)increases gradually from inside to outside, and distances of each adjacent two of the circumferences of the plurality of sequentially nested circle(s) decrease gradually from inside to outside.

In an embodiment of the disclosure, the center of the circle(s) is arranged with the semiconductor chip. And on any connecting line from the center to an outmost circumference, distances from each of the circumferences of the plurality of sequentially nested circle(s) and the center satisfy a relationship that R₁≧(R₂−R₁)≧(R₃−R₂)≧ . . . ≧ (R_{N}−R_{N-1})>b, wherein R₁, R₂, R₃, . . . , R_{N-1} and R_{N} are the distances from each of the circumferences of the plurality of sequentially nested circle(s) to the center on the connecting line respectively, wherein b is a width of the semiconductor chips and a length of the semiconductor chips is larger than or equal to b, wherein N is a natural number and a value of N depends on the total amount of the plurality of semiconductor chips.

In an embodiment of the disclosure, the center of the circle(s) is not arranged with the semiconductor chip. And on any connecting line from the center to the outmost circumference, distances from the respective circumferences of the plurality of sequentially nested circle(s) to the center satisfy a relationship that 2 R₁≧(R₂−R₁)≧(R₃−R₂)≧ . . . ≧(R_{N}−R_{N-1})>b, wherein R₁, R₂, R₃, . . . , R_{N-1} and R_{N} respectively are the distances from the respective circumferences of the plurality of sequentially nested circle(s) to the center on the connecting line, wherein b is a width of the semiconductor chips and a length of the semiconductor chips is larger than or equal to b, wherein N is a natural number and a value of N depends on the total amount of the plurality of semiconductor chips.

In an embodiment of the disclosure, when a minimum radian between two adjacent semiconductor chips on an Nth circumference from inside to outside is c, and a minimum radian between two adjacent semiconductor chips on an (N−1)th circumference from inside to outside is d, and c and d satisfy that d≧c.

In an embodiment of the disclosure, heat dissipation spaces of each semiconductor chips on any connecting line from the center of the circle(s) to the outmost circumference along a direction from inside to outside are gradually decreased. For the most part, the heat dissipation space of a semiconductor chips is defined as a circular region with the semiconductor chip as the center and a minimum distance from the center to an adjacent semiconductor chip as the radius. However, when a minimum distance from a semiconductor chip on the outmost circumference to the edge of the die bonding region of the substrate is shorter than that to an adjacent semiconductor chip, the heat dissipation space of the semiconductor chip is defined as a circular region with the distance of the semiconductor chip on the outmost circumference and the edge of the die bonding region as the radius.

In an embodiment of the disclosure, the substrate is a mirror aluminum substrate or a ceramic substrate.

In an embodiment of the disclosure, the semiconductor chips are light-emitting diode chips.

Moreover, a manufacturing method of a semiconductor element provided by an embodiment of the disclosure includes steps: (i) setting target circular regions on a substrate according to a radius of a die bonding region; (ii) placing predetermined number of semiconductor chips in the target circular regions on the substrate in a form of equidistant arrangement; (iii) according to left and right remaining spaces of each row of semiconductor chips in the target circular region, increasing spaces on the row direction among semiconductor chips in the row of the semiconductor chips, increased proportions of the spaces for the semiconductor chips are decreased along directions towards two ends of the row; (iv) according to upper and lower remaining spaces in the target circular region, increasing spaces on the column direction between semiconductor chips in each two adjacent rows of semiconductor chips, increased proportions of the spaces for the semiconductor chips are decreased along directions towards two ends of the two adjacent rows; and (v) according to a rule that heat dissipation spaces of each of the semiconductor chips in the predetermined number of semiconductor chips gradually decrease from a center to an outmost circumference, slightly adjusting positions of the predetermined number of semiconductor chips, the heat dissipation space is defined as a circular region with the center of the semiconductor chip as a center of a circle and the minimum distance from the center to an adjacent semiconductor chip and to an edge of the die bonding region as a radius.

In an embodiment of the disclosure, the substrate in the manufacturing method of a semiconductor element is a mirror aluminum substrate or a ceramic substrate.

In an embodiment of the disclosure, the semiconductor chips in the manufacturing method of a semiconductor element are light-emitting diode chips.

It can be learnt from the above that the embodiments of the disclosure optimize the arrangement of the semiconductor chips such as light-emitting diode chips to arrange the semiconductor chips to be loose in the center and dense from the center towards outside, which can distribute heat evenly, so as to slow down aging and failure of the semiconductor chips, as well as improving heat dissipation performance and light-emitting effects of a product.

By the following detailed description with reference to accompanying drawings, other aspects and features of the disclosure will become apparent. However, it should be understood that, the drawings only are for the purpose of explanation and not as limiting the scope of the disclosure. It also be appreciated that, unless otherwise indicated, the drawings are not necessarily drawn to scale, they are merely trying to conceptually illustrate the structures and procedures described herein.

### BRIEF DESCRIPTION OF THE DRAWINGS

In the following, with reference to accompanying drawings, concrete embodiments of the disclosure will be described in detail.

FIG. 1 is a schematic view of conventional equidistantly arranged LED chips.

FIG. 2 is a schematic view of distances from circumferences of a plurality of circles or approximate circles with a common center formed by arranging a plurality of semiconductor chips in a semiconductor element to the center according to an embodiment of the disclosure.

FIG. 3 is a structural schematic view of a semiconductor element according to an embodiment of the disclosure.

FIG. 4 is a schematic view of a manufacturing method of a semiconductor element according to an embodiment of the disclosure.

FIGS. 5A-5D are schematic views of various arrangements of a plurality of semiconductor chips according to other embodiments of the disclosure.

### DETAILED DESCRIPTION OF PREFERRED EMBODIMENTS

Embodiments of the disclosure are described in detail with reference to the accompanying drawings as follows to better understand the previously mentioned objectives, features and advantages of the disclosure.

Embodiments of the disclosure below will provide an optimized circular arrangement, which can improve heat dissipation property and light-emitting effect of product thoroughly. It should be noted that “circular arrangement” of the embodiments of the disclosure below indicates more than an ideal circular arrangement, other approximate circular arrangements can be included as well, such as an ellipse or other irregular circles arrangements, but centers of various approximate circles are the same point (i.e., concentric circles) or the centers have little deviation thereamong. And “circular(s)” of the embodiments of the disclosure below indicated an ideal circular and other approximate circulars, too. Herein, it should be understood that the ideal circle has a single radius, while the approximate circle has multiple (i.e., more than one) different radii.

To be more specific, with regard to a circular arrangement provided by an embodiment of the disclosure, a plurality of semiconductor chips such as light-emitting diode chips are arranged on a substrate such as a mirror aluminum substrate or a ceramic substrate to form a plurality of nested circle(s) and/or approximate circle(s) in sequence, i.e., centers of the circle(s) are located in the innermost circle or approximate circle, on any connecting line from the center to an outmost circumference, distances from circumferences of the circle(s) to the center satisfy a certain relationship, by using the relationship to arrange the semiconductor chips, efficiency of design can be improved and an optimized circular arrangement can be found rapidly.

The relationship is primarily divided into two situations as follows.

(1) The center is disposed with a chip.

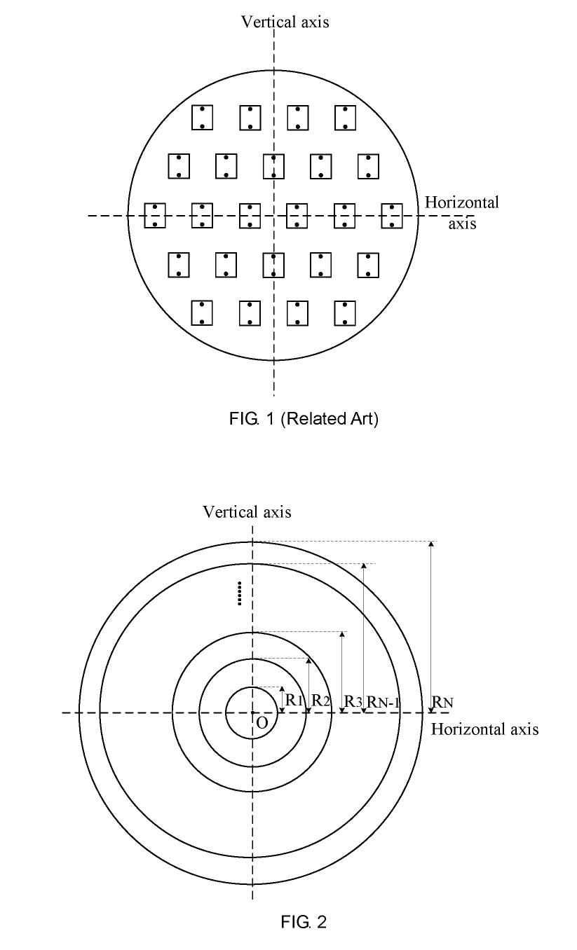

Variables a and b are defined to represent a length and a width of a chip, and alp, R₁, R₂, R₃, . . . , R_{N-1} and R_{N} respectively indicate distances from the circumferences of respective circle(s) to the center O on a same connecting line from the center O to the outmost circumference (see FIG. 2). The variables and the distances satisfy a relationship that R₁≧(R₂−R₁)≧(R₃−R₂)≧ . . . ≧(R_{N}−R_{N-1})>b, wherein N is a natural number and a value of N depends on the total amount of the chips. It can be known from the relationship of R₁≧(R₂−R₁)≧(R₃−R₂)≧ . . . ≧(R_{N}−R_{N-1})>b that distances between each two adjacent circumferences in a radial direction are gradually reduced. Moreover, based on the relationship, the following relationships further can be obtained:

b/R₁<(R₂−R₁)/R₁≦

b/(R₂−R₁)<(R₃31 R₂)/(R₂−R₁)≦1

b/(R_{N-1}−R_{N-2})<(R_{N}−R_{N-1})/(R_{N-1}−R_{N-2})≦1.

Furthermore, the numbers of chips on respective circumferences of the circles or approximate circles from inside to outside are gradually increased, which means arrangement densities of chips correspondingly are increased. It is assumed that a minimum radian between two adjacent chips on a circumference of the Nth circle or approximate circle numbered from inside to outside is c, and a minimum radian between two adjacent chips on a circumference of the (N−1)th circle or approximate circle is d, then c and d satisfy that: d≧c. It can be understood that if chips on a same circumference are equidistantly arranged along the circumferential direction, c and d satisfy that d>c.

(2) The center does not be disposed with chip.

Variables a and b are defined to represent a length and a width of a chip, and a≧b, R₁, R₂, R₃, . . . , R_{N-1} and R_{N} respectively indicate distances from circumferences of respective circle(s) to the center O on a same connecting line from the center O to the outmost circumference (still referring to FIG. 2). The variables and the distances satisfy a relationship that 2 R₁≧(R₂−R₁)≧(R₃−R₂)≧ . . . ≧(R_{N}−R_{N-1})>b, wherein N is a natural number and a value of N depends on the total amount of the chips. It can be known from the relationship of 2 R₁≧(R₂−R₁)≧(R₃−R₂)≧ . . . ≧(R_{N}−R_{N-1})>b that distances between each two adjacent circumferences in an radial direction are gradually reduced. Moreover, according to the relationship, relationships can further be obtained as follows:

b/2R₁<(R₂−R₁)/2R₁≦1

b/(R₂−R₁)<(R₃−R₂)/(R₂−R₁)≦1

b/(R_{N-1}−R_{N-2})<(R_{N}−R_{N-1})/(R_{N-1}−R_{N-2})≦1.

Moreover, the numbers of chips on respective circumferences of the circles or approximate circles from inside to outside are gradually increased, which means arrangement densities of chips correspondingly are increased. If a minimum radian between two adjacent chips on a circumference of the Nth circle or approximate circle numbered from inside to outside is assumed to be c, and a minimum radian between two adjacent chips on a circumference of the (N−1)th circle or approximate circle is assumed to be d, c and d satisfy that: d≧c. It can be understood that if chips on a same circumference are equidistant arrangement on the circumferential direction, c and d satisfy that d>c.

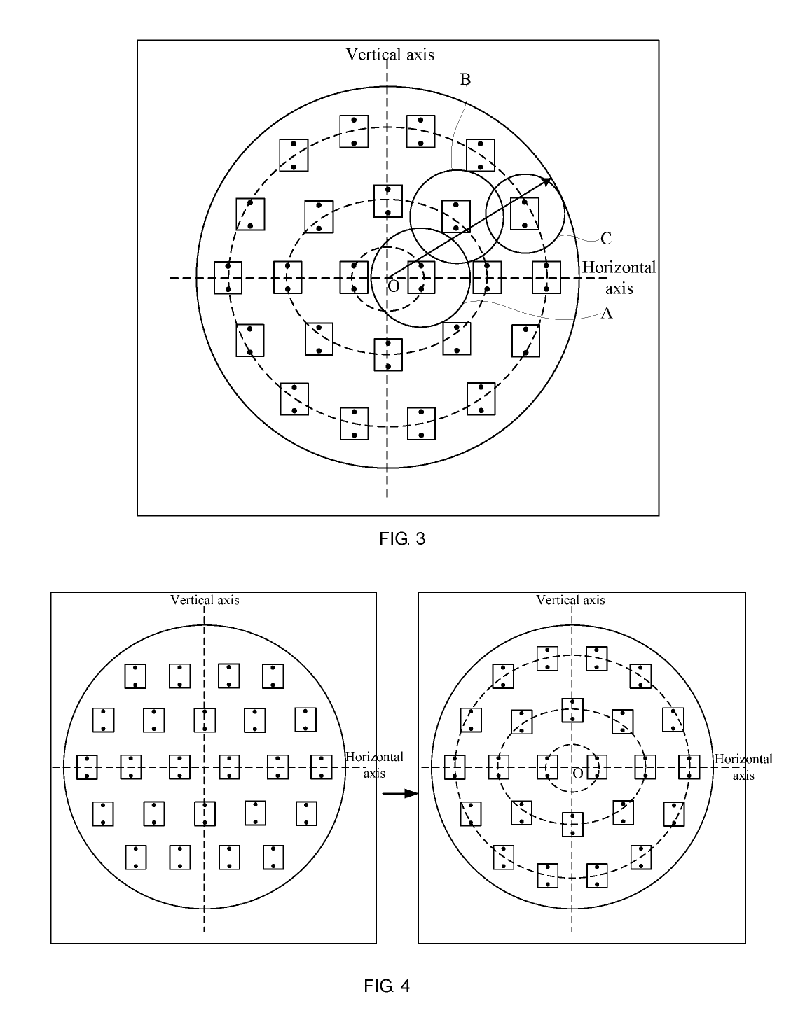

Moreover, referring to FIG. 3, regarding to any connecting line from the center O to the outmost circumference (e.g., the arrowed straight line in FIG. 3), heat dissipation spaces corresponding to each chip on the connecting line from inside to outside decrease gradually. Herein, it is taken in account that heat of chip outwardly diffuse in the form of similar circular arc shape, the heat dissipation space of a semiconductor chip is defined as a circular region with a center being a geometrical center of the chip and a radius being a minimum distance from the center to an adjacent chip, such as regions A and B in FIG. 3. However, when the distance of a geometrical center of the chip on the outmost circumference to the edge of a die bonding region (solid circular region in which all chips are arranged as shown in FIG. 3) is supposed to be shorter, the distance is regarded as the radius of the circular region, such as region C in FIG. 3. Therefore, the circular arrangement provided by the embodiment satisfies the following condition that: A≧B≧C. In other words, the heat dissipation space of a semiconductor can be defined as a circular region with the geometrical center of the chip as the center and the minimum one of the distances of the center to an adjacent chip and to the edge of the die bonding region as the radius.

It can be learned from above that, a heat dissipation optimization principle of the circular arrangement provided by the embodiments of the disclosure is that the numbers of chips on respective circumferences from inside to outside increase gradually, and densities of chips on respective circumferences from inside to outside gradually increase correspondingly, which would cause the chip arrangement is loose in the center and more dense towards outside. In general, heat of chips in the central region is primarily dissipated through the substrate at the bottom, chips in the peripheral region further can be dissipated towards the edges, which would lead to a circumstance of high temperature in the central region and low temperature on edges, chips in the central region are aging and failed rapidly due to the high temperature, the service period of the entire product is reduced. The chip arrangement of being loose in central region while more dense towards outside according to the embodiment can optimize the situation, so that heat can be distributed evenly.

A method for realizing a multiple chips circular arrangement shown in FIG. 3 will be described below with reference to FIG. 4.

It is supposed that a packaging substrate adopts COB mirror aluminum, a radius R of a circular die bonding region of the mirror aluminum substrate is 4.75 millimeters (mm), a size of the chip is 26 mil*30 mil, and the number of the chips is 24.

1) a target circular region is obtained by using the center of the mirror aluminum substrate (rectangular region in FIG. 4) as the center of circle and using (R−0.5 millimeters) as a radius and then is treated as an arrangement region of the chips.

2) all the chips are arranged to be equidistant and disposed in the target circular region, as shown on the left side of FIG. 4.

3) spaces in a row direction (horizontal direction) among the chips in each row are increased according to left and right remaining spaces of the row in the target circular region, and increased proportions are decreased from middle to two sides (i.e., the farther the chip away from the vertical axis, the smaller the increased proportion of the space in the row direction is).

4) spaces in a column direction (vertical direction) between chips in each two adjacent rows are increased according to upper and lower remaining spaces of the target circular region, and increased proportions are smaller towards the two sides (i.e., the farther the chip away from the vertical axis, the smaller the increased proportion of the space in the column direction is).

5) the circular arrangement provided by the embodiment of the disclosure can be preliminarily obtained according to the previous steps, and finally according to a method of drawing circles as the heat dissipation spaces shown in FIG. 3, as per a rule that heat dissipation spaces decrease gradually from the center O to the outmost circumference, a semiconductor element shown as FIG. 3 or shown on the right side of FIG. 4 can be obtained by slightly adjusting positions of the chips.

Of course, it can be understood that the circular arrangement of the multiple chips shown in FIG. 3 can be achieved by other method instead, for example, firstly determining positions of respective circle(s) in the circular die bonding region and arrangement positions of the chips on respective circumferences of the circle(s) according to the rule of circular arrangement of multiple chips provided by the embodiment of the disclosure, and then disposing the chips on the determined positions on the respective circumferences directly.

To be more specific, in FIG. 3, the semiconductor element includes a substrate (denoted by rectangular region) and a plurality of chips such as light-emitting diode chips disposed on the substrate, the plurality of chips are arranged to form a plurality of concentric (one type of sequentially nested structure) approximate circles denoted as dotted lines in FIG. 3 (of course, circles are another option), each of the approximate circles has multiple chips arranged its circumference. Moreover, the numbers of the chips arranged on respective circumferences of the approximate circles increase gradually from inside to outside (e.g., 2, 8 and 14 number of chips from inside to outside in sequence as shown in FIG. 3) and distances of among the circumferences of the approximate circles decrease gradually from inside to outside, and heat dissipation spaces (i.e. A, B, C) corresponding to the chips on any one connecting line (e.g., the arrowed straight line in FIG. 3) from the center O to the outmost circumference decrease gradually. Of course, it can be understood that, according to the foregoing description, it can be found that the center O may be disposed with a chip or does not be disposed with chip.

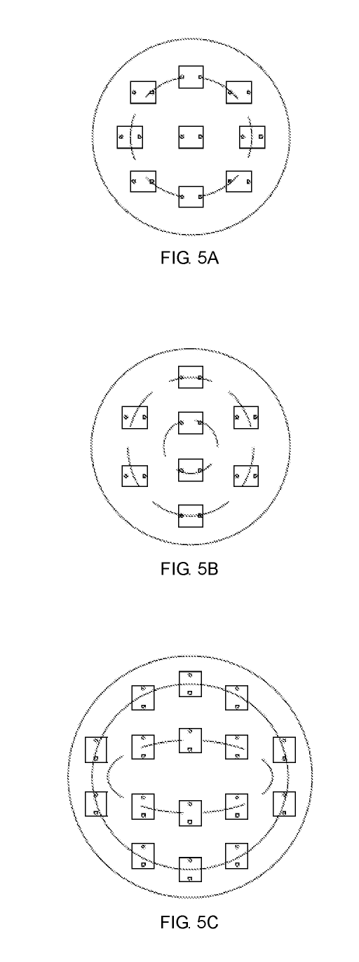

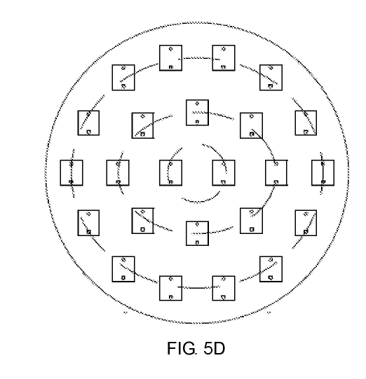

Finally, in order to make the skilled in the art more clearly understand the circular arrangement rule of multiple chips of the disclosure, much more examples associated with different circular arrangements of multiple chips will be listed as follows, such as shown in FIGS. 5A-5D. In FIG. 5A, the center has a chip disposed thereat. In FIG. 5B, the center does not be disposed with chip. In FIG. 5C, the center does not be disposed with chip, and one circle and one approximate circle are nested together. In FIG. 5D, the center does not be disposed with chip, and one circle and two approximate circles are nested together. Moreover, it needs to be noted that regarding to the chips on each of the circumferences from inside to outside, a size of the chips on the outmost circumference may be different from a size of the chips on other circumferences.

In summary, each of the embodiments of the disclosure optimizes the arrangement of the semiconductor chips such as light-emitting diode chips to make the arrangement the semiconductor chips be loose in the central region while more dense towards outside, which is in favor of uniform heat distribution and thus can slow down aging and failure of the semiconductor chips as well as improve heat dissipation property and light-emitting effect of product.

The above description illustrates preferred embodiments of the disclosure rather than any limitation, though the preferred embodiments are disclosed previously, the disclosure needs not be limited to the disclosed embodiments. For those skilled persons in the art, various modifications and variations can be made according to the concept of the disclosure. It is intended to cover various modifications and similar arrangements included within the spirit and scope of the appended claims that are to be accorded with the broadest interpretation so as to encompass all such modifications and similar structures.

What is claimed is:

1. A semiconductor element comprising a substrate and a plurality of semiconductor chips disposed on the substrate; wherein the plurality of semiconductor chips are arranged to form a plurality of sequentially nested circle(s), and the circumference of each of the circle(s) is arranged with a plurality of the semiconductor chips thereon; numbers of the semiconductor chips arranged on the respective circumferences of the plurality of sequentially nested circle(s) from inside to outside are gradually increased, and distances of every adjacent two of the circumferences of the plurality of sequentially nested circle(s) from inside to outside are gradually decreased.

2. The semiconductor element according to claim 1, wherein the center of the circle(s) is arranged with the semiconductor chip, and on any one connecting line from the center to the outmost circumference, distances from the circumferences of the plurality of sequentially nested circle(s) to the center satisfy a relationship that: R₁≧(R₂−R₁)≧(R₃−R₂)≧ . . . ≧(R_{N}−R_{N-1})>b; where R₁, R₂, R₃, . . . , R_{N-1} and R_{N} are the distances from the circumferences of the plurality of sequentially nested circle(s) to the center on the connecting line respectively, wherein b is a width of the plurality of semiconductor chips and a length of the plurality of semiconductor chips is larger than or equal to b, wherein N is a natural number and a value of N depends on the total amount of the plurality of semiconductor chips.

3. The semiconductor element according to claim 1, wherein the center of the circle(s) does not be arranged with the semiconductor chip, and on any one connecting line from the center to the outmost circumference, distances from the respective circumferences of the plurality of sequentially nested circle(s) to the center satisfy a relationship that: 2 R₁≧(R₂−R₁)≧(R₃−R₂)≧ . . . ≧(R_{N}−R_{N-1})>b; where R₁, R₂, R₃, . . . , R_{N-1} and R_{N} respectively are the distances from the respective circumferences of the plurality of sequentially nested circle(s) to the center on the connecting line, wherein b is a width of the plurality of semiconductor chips and a length of the plurality of semiconductor chips is larger than or equal to b, wherein N is a natural number and a value of N depends on the total amount of the plurality of semiconductor chips.

4. The semiconductor element according to claim 1, wherein a minimum radian between two adjacent semiconductor chips on an Nth circumference from inside to outside is c, and a minimum radian between two adjacent semiconductor chips on an (N−1)th circumference from inside to outside is d, and c and d satisfy that: d≧c.

5. The semiconductor element according to claim 1, wherein heat dissipation spaces of respective semiconductor chips on any one connecting line from a center of the circle(s) to the outmost circumference along a direction from inside to outside are gradually decreased; wherein the heat dissipation space of a semiconductor is defined as a circular region with the geometrical center of the chip as the center and the minimum one of the distances of the center to an adjacent chip and to the edge of the die bonding region as the radius.

6. The semiconductor element according to claim 1, wherein the substrate is a mirror aluminum substrate or a ceramic substrate.

7. The semiconductor element according to claim 1, wherein the semiconductor chips are light-emitting diode chips.

8. A manufacturing method of a semiconductor element, wherein it comprises steps:
setting a target circular region on a substrate according to a radius of a die bonding region;
placing predetermined number of semiconductor chips in the target circular region on the substrate in a form of equidistant arrangement;
according to left and right remaining spaces of each row of semiconductor chips in the target circular region, increasing spaces on the row direction among semiconductor chips in the row of the semiconductor chips, wherein increased proportions of the spaces for the semiconductor chips are decreased along directions towards two ends of the row;
according to upper and lower remaining spaces in the target circular region, increasing spaces on the column direction between semiconductor chips in each two adjacent rows of semiconductor chips, increased proportions of the spaces for the semiconductor chips are decreased along directions towards two ends of the two adjacent rows; and
according to a rule that heat dissipation spaces of respective semiconductor chips in the predetermined number of semiconductor chips are gradually decreased from a center to an outmost circumference, slightly adjusting positions of the predetermined number of semiconductor chips, wherein the heat dissipation space of each the semiconductor chip is defined as a circular region with a center of the semiconductor chip as a center and the minimum one of distances from the center to an adjacent semiconductor chip and to an edge of the die bonding region as a radius.

9. The manufacturing method of a semiconductor element according to claim 8, wherein the substrate is a mirror aluminum substrate or a ceramic substrate.

10. The manufacturing method of a semiconductor element according to claim 8, wherein the semiconductor chips are light-emitting diode chips.
